(19) United States
(12) Patent Application Publication
(10) Pub. No.: US 2014/0318615 A1
(43) Pub. Date: Oct. 30, 2014

(54) CONDUCTIVE COMPOSITION, SILICON SOLAR CELL INCLUDING THE SAME, AND MANUFACTURING METHOD THEREOF

(71) Applicant: ELECTRONICS AND TELECOMMUNICATIONS RESEARCH INSTITUTE, Daejeon (KR)

(72) Inventors: Soo Young OH, Daejeon (KR); Yong Sung EOM, Daejeon (KR); Jong Tae MOON, Gyeryong-si (KR); Kwang Seong CHOI, Daejeon (KR)

(73) Assignee: ELECTRONICS AND TELECOMMUNICATIONS RESEARCH INSTITUTE, Daejeon (KR)

(21) Appl. No.: 14/325,203

(22) Filed: Jul. 7, 2014

Related U.S. Application Data
(62) Division of application No. 13/411,501, filed on Mar. 2, 2012.

(30) Foreign Application Priority Data
Mar. 2, 2011 (KR) 10-2011-0018577
Dec. 21, 2011 (KR) 10-2011-0139645

(51) Int. Cl. H01L 31/0224

(52) U.S. Cl. CPC H01L 31/022425
USPC 136/256

(57) ABSTRACT

A conductive composition for a front electrode busbar of a silicon solar cell includes a metallic powder, a solder powder, a curable resin, a reducing agent, and a curing agent. A method of manufacturing a front electrode busbar of a silicon solar cell includes applying the composition to the front surface of the silicon solar cell wherein its front electrode finger line is formed. A substrate includes a front electrode busbar of a silicon solar cell, formed with a conductive composition. A silicon solar cell includes one or more electrodes containing a conductive composition including a conductive powder, a curable resin, a reducing agent, and a curing agent. A method of manufacturing the silicon solar cell includes forming a first electrode array with a first conductive composition, forming a second electrode, and forming a third electrode with a third conductive composition.

### CROSS-REFERENCE TO RELATED APPLICATIONS

This is a divisional of co-pending U.S. application Ser. No. 13/411,501, filed Mar. 2, 2012. This U.S. non-provisional patent application is based on and claims priority from Korean Patent Application No. 2011-0018577, filed on Mar. 2, 2011, and Korean Patent Application No. 2011-0139645, filed on Dec. 21, 2011, with the Korean Intellectual Property Office, the disclosure of which is incorporated herein in its entirety by reference.

### TECHNICAL FIELD

This invention relates to a conductive composition, a silicon solar cell including the same, and a manufacturing method thereof.

### BACKGROUND

As industries develop, use of fossil fuels increases and it causes problems that energy resources are exhausted and the climate is changed due to global warming In order to solve the problems, research and development on solar power generation using solar energy as an energy source, which is infinite clean energy, has progressed all over the world. Nevertheless, since costs for the present solar power generation are expensive as compared with power generation based on the existing fossil fuels, there was a problem in that economic efficiency thereof is deteriorated. Therefore, in the solar power generation, a lot of researches and developments for low-costs of the solar power generation based on Grid parity where costs for the existing power generation are the same as those for the solar power generation are being conducted.

Solar cells used for the solar power generation may be classified into a silicon solar cell, a compound semiconductor solar cell, a tandem solar cell, and the like depending upon a material. Currently, among them, the silicon solar cell with guaranteed reliability is being mainly (80% or more) used. However, since the silicon solar cell uses high-priced materials such as silicon as a substrate, and a silver paste as electrodes, it is required to reduce the prices of the materials or replace the high-priced material with low-priced materials in order to ensure the Grid parity.

A structure of a silicon solar cell in prior art, and a manufacturing process thereof are as follows:

(1) Formation of p-type silicon wafer substrate: First, a p-type silicon wafer substrate is formed.

(2) Formation of p-n junction structure: An n-type layer is formed on the entire surface of the silicon wafer substrate by thermally diffusing pentavalent elements such as phosphorus or the like on the p-type silicon wafer substrate. As a result, a p-n junction between the p-type silicon wafer and the n-type layer is formed.

(3) Removal of rear n-type layer: The n-type layer of the front surface of the silicon wafer substrate is protected with a photoresist, the n-type layer of the rear surface thereof is removed through etching, and then, the photoresist of the n-type layer is removed by using organic solvent.

(4) Formation of anti-reflection film: Silicon nitride film (SiNx) as an anti-reflection film is deposited on the n-type layer by a plasma enhanced chemical vapor deposition (PECVD).

(5) Formation of electrodes: A front electrode of the silicon wafer substrate is generally formed of an H-pattern, which has a finger line formed with several parallel lines and busbars perpendicular to the finger line and with a width of 1.5 to 2 mm between the busbars. The finger line and the busbars are simultaneously printed with a silver paste for a front electrode by a screen printing, and dried. An aluminum paste for a rear electrode is coated and dried over the rear surface of the silicon wafer. In order to connect to a copper ribbon coated with the solder used for connection with another silicon solar cell, an aluminum/silver paste for rear busbars with a width of 1 to 2 mm is printed on the aluminum rear electrode by a screen printing, and dried. The dried front electrode and rear electrode are fired at a high temperature of 700° C. or more. By the firing, aluminum of the aluminum paste for a rear electrode is diffused to the silicon substrate to form a P+ layer, the aluminum paste is transformed into the aluminum rear electrode, and the aluminum/silver paste is transformed into the aluminum/silver rear electrode busbar. Simultaneously, by the firing, a fire-through phenomenon in which the silver paste for a front electrode fires through the silicon nitride film occurs such that the silver paste is electrically connected with the n-type layer and that the finger line and the busbar are transformed into the front electrode.

The silver, which is included not only in the finger line and the busbar of the silver front electrode but also in the aluminum/silver rear electrode busbar, is a high-priced rare metal and the price thereof is rapidly increasing. Particularly, since the silver is used for the solar cell which increases by 30 to 40% or more every year, it is expected that the price will more rapidly increase. Accordingly, in order to widely use the silicon solar cell, it is necessary to reduce the use of the high-priced silver paste material or replace the high-priced silver paste material with other materials.

WO92/22928 discloses a solar cell which uses a silver paste as the front electrode busbar. In the document, the front electrode is printed in two processes. The front electrode finger line is printed with a material capable of firing through the anti-reflection film such as a silicon nitride film (for example, a paste containing silver and glass flit particles) and the front electrode busbar is printed and fired with a silver paste (for example, a silver-epoxy paste) made of a material which does not fire through the anti-reflection film. Since a metal/silicon contact surface is not formed below the front electrode busbar, the re-combination of the electrons and the holes is minimized, such that the open-circuit voltage of the silicon solar cell increases and as a result, conversion efficiency of the silicon solar cell is excellent.

In this case, the silver paste is used for the front electrode busbar. During the firing, silver oxide is produced from the silver paste. Since the silver oxide is a conductor, an electric adhesion between metal particles in the paste or with the copper ribbon coated with the solder for connecting many silicon solar cells with each other when manufacturing a solar cell module is firmly performed.

As described above, considering that the silver material is expensive, when pastes of other metallic powders (copper, nickel, solder, and the like) other than silver as the material of the electrode busbar are used, printed, and fired, oxide films of the metals are formed. The oxide films are nonconductors, which cause a problem that a mechanical and electrical connection between metal particles in the paste or with the copper ribbon coated with the solder for connecting many silicon solar cells with each other when manufacturing a solar cell module is not firmly performed.

### SUMMARY

This invention has been made in an effort to provide a conductive composition for a front electrode busbar of a silicon solar cell. This invention has also been made in an effort to provide a method of manufacturing a front electrode busbar of a silicon solar cell using the conductive composition and a substrate comprising the front electrode busbar of the silicon solar cell formed with the conductive composition.

This invention has also been made in an effort to provide a silicon solar cell comprising a conductive composition including a conductive powder, a curable resin, a reducing agent, and a curing agent.

This invention has also been made in an effort to provide a method of manufacturing the silicon solar cell.

An exemplary embodiment of this invention provides a composition used in a manufacturing of a front electrode busbar of a silicon solar cell, comprising a metallic powder; a solder powder; a curable resin; a reducing agent; and a curing agent.

Another exemplary embodiment of this invention provides a method of manufacturing a front electrode busbar of a silicon solar cell, comprising: applying the composition instead of a silver paste of prior art to the front surface of the silicon solar cell wherein its front electrode finger line is formed, printing and drying the composition at the front electrode busbar of the silicon solar cell to form a substrate, and heating the substrate at a melting point or more of a solder powder; and a substrate comprising the front electrode busbar formed with the conductive composition.

Yet another exemplary embodiment of this invention provides a silicon solar cell comprising a front electrode busbar formed with a conductive composition including a conductive powder, a curable resin, a reducing agent, and a curing agent. The reducing agent is added to the conductive composition for the front electrode busbar, and thus, an oxide film formed by a conductive powder in the conductive composition during the firing is removed, metallic powders are electrically contacted with each other, thereby solving an electric non-contact problem.

Still another exemplary embodiment of this invention provides a method of manufacturing a silicon solar cell comprising: forming a first electrode array with a composition including a metallic powder and a glass flit; forming a second electrode; and forming a third electrode with a composition including a conductive powder, a curable resin, a reducing agent, and a curing agent.

According to the exemplary embodiments of this invention, it is possible to provide a new silicon solar cell with excellent photovoltaic efficiency or a new silicon solar cell which is economical while having the same level of photovoltaic efficiency; and a manufacturing method thereof. That is, in the silicon solar cell according to the exemplary embodiment of this invention, it is possible to solve a non-contact problem due to the generation of a metal oxide film by using a conductive composition comprising a conductive powder, a curable resin, a reducing agent, and a curing agent as a material of a front electrode busbar and to increase photovoltaic efficiency of the cell by increasing open circuit voltage of the solar cell because the conductive composition itself does not fire through a silicon nitride film and therefore not to form the contact surface with an n-type layer. If copper and nickel are contained as a metallic paste, economic efficiency can be improved.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating a silicon solar cell manufactured according to an exemplary embodiment of this invention.

FIGS. 2A to 2G illustrate a manufacturing process of a silicon solar cell according to an exemplary embodiment of this invention.

FIG. 3 is a scanning electron microscopic (SEM) photograph illustrating a flake copper powder used in an exemplary embodiment of this invention.

FIG. 4 is an SEM photograph illustrating a solder powder used in an exemplary embodiment of this invention.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

An exemplary embodiment of present disclosure provides a composition used in a manufacturing of a front electrode busbar of a silicon solar cell, comprising a metallic powder; a solder powder; a curable resin; a reducing agent; and a curing agent.

Another exemplary embodiment of this invention provides a method of manufacturing a front electrode busbar of a silicon solar cell comprising: applying the composition instead of a silver paste of the prior art to the front surface of the silicon solar cell wherein its front electrode finger line is formed to print and dry the composition at the front electrode busbar of the silicon solar cell to form a substrate, and heating the substrate at a melting point or more of a solder powder; and provides a substrate comprising the front electrode busbar formed with the conductive composition.

Yet another exemplary embodiment of this invention provides a silicon solar cell, comprising:

a silicon substrate having a p-n junction structure;

an anti-reflection film layer formed at the front surface of the silicon substrate;

a first electrode array electrically and mechanically connecting to the front surface of the silicon substrate by passing through the anti-reflection film layer;

a second electrode formed at the rear surface of the silicon substrate; and

one or more third electrode electrically and mechanically connecting to the first electrode array, which is not connected with the front surface of the silicon substrate, and contains a conductive composition comprising a conductive powder, a curable resin, a reducing agent, and a curing agent.

Still another exemplary embodiment of this invention provides a method of manufacturing a silicon solar cell, comprising:

(1) forming a silicon substrate having a p-n junction structure;

(2) forming an anti-reflection film layer at the front surface of the silicon substrate;

(3) forming a first electrode array by printing, drying, and firing a first conductive composition including a metallic powder and a glass flit on the anti-reflection film layer and firing the first conductive composition through the anti-reflection film to electrically and mechanically connect to the front surface of the silicon substrate;

(4) forming a second electrode by printing and firing a second conductive composition including a metallic powder and a glass flit on the rear surface of the silicon substrate; and

(5) forming a third electrode by printing, drying, and firing a third conductive composition including a conductive powder, a curable resin, a reducing agent, and a curing agent on the anti-reflection film and the first electrode array to mechanically connect to the anti-reflection film, to electrically and mechanically connect to the first electrode, and not to be connected with the front surface of the silicon substrate.

Hereinafter, the exemplary embodiments of this invention will be described in detail with reference to the drawings.

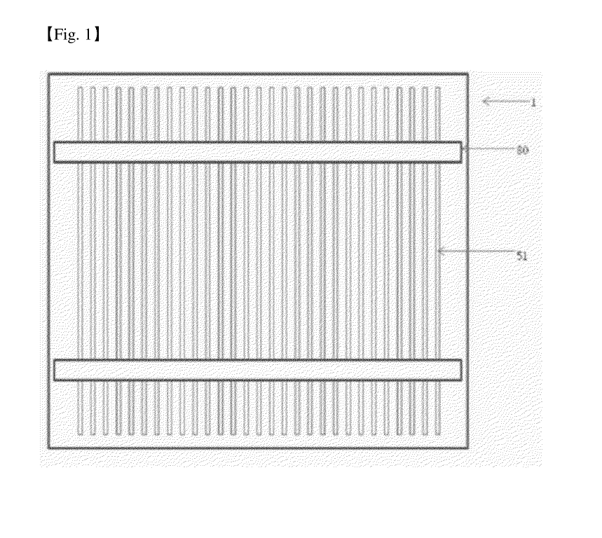

FIG. 1 is a plan view illustrating a silicon solar cell 1 manufactured according to an exemplary embodiment of this invention.

An electrode, which includes a finger line 51 collecting electrons generated by light and a busbar 80 for connecting a copper ribbon coated with a solder used for connecting the finger line 51 with another silicon solar cell, is disposed at the front surface of the silicon solar cell. In the conventional silicon solar cell, a finger line and a busbar of a front electrode are printed with a silver paste, dried, and then, fired at a high temperature of 700° C. or more. The silver paste fires through a silicon nitride film by firing to be electrically connected with an n-type layer. Meanwhile, in the silicon solar cell according to the exemplary embodiment of this invention, the front electrode busbar is printed with a conductive composition comprising a conductive powder and a reducing agent instead of the conventional silver paste, dried and then, fired at a low temperature. In the case of using copper or the like as the conductive powder, a general high-priced silver paste used for manufacturing the front electrode busbar of the silicon solar cell may be replaced with a low-priced conductive composition, thereby lowering a price of the silicon solar cell. The conductive composition for a busbar according to the exemplary embodiment of this invention does not fire through the silicon nitride film so as not to form a contact surface with the n-type layer. Thus, re-combination of electrons and holes may be minimized in a region below the busbar. Accordingly, open circuit voltage of the silicon solar cell is increased to increase conversion efficiency.

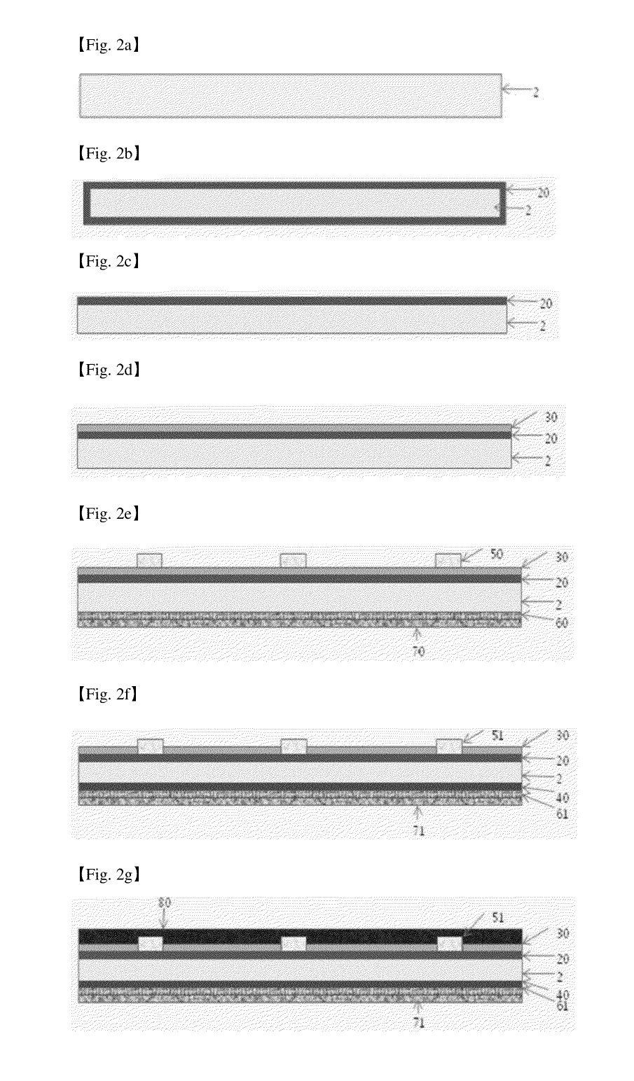

FIGS. 2A to 2G illustrating a manufacturing process of one example of a silicon solar cell according to an exemplary embodiment of this invention. Referring to FIGS. 2A to 2G, a manufacturing process of a silicon solar cell according to an exemplary embodiment of this invention will be described in detail.

(1) Formation of p-type silicon wafer substrate: First, a p-type silicon wafer substrate 2 is formed. FIG. 2A shows the p-type silicon wafer substrate 2 used for manufacturing the solar cell.

(2) Formation of p-n junction structure: An n-type layer 20 is formed on the entire surface of the substrate 2 by thermally diffusing pentavalent elements such as phosphorus or the like on the p-type silicon wafer substrate 2, as shown in FIG. 2B. As a result, a p-n junction between the p-type silicon wafer and the n-type layer is formed. FIG. 2B shows a state where the n-type layer 20 is formed on the p-type silicon wafer substrate 2 to form the p-n junction.

(3) Removal of rear n-type layer: The n-type layer 20 of the front surface of the p-type silicon wafer substrate 2 is protected with a photoresist, the n-type layer 20 of the rear surface of the substrate 2 is removed through etching, and then, the photoresist for protecting the n-type layer 20 is removed by using organic solvent. Accordingly, as shown in FIG. 2C, only the n-type layer 20 remains at the front surface of the p-type silicon wafer substrate 2.

(4) Formation of anti-reflection film: Next, as shown in FIG. 2D, a silicon nitride film (SiNx) as an anti-reflection film 30 is deposited on the front n-type layer 20 by a plasma enhanced chemical vapor deposition (PECVD).

(5) Formation of electrode: As shown in FIG. 2E, only a silver paste 50 for the front electrode to configure the front electrode finger line is printed and dried at the front surface of the p-type silicon wafer substrate 2 by screen printing. An aluminum paste 60 for a rear electrode is coated at the rear surface of the p-type silicon wafer substrate 2, and dried. On the aluminum rear electrode, an aluminum/silver paste 70 for a rear busbar is printed by screen printing, and dried. The aluminum/silver paste 70 is used for connection with a copper ribbon coated with a solder used for connection with another silicon solar cell and mainly has a width of 1.5 to 2 mm.

(6) Firing: Next, the aforementioned cell is fired at a high temperature of 700° C. or more in order to form the front electrode finger line, the rear electrode, and the rear electrode busbar. During the firing, aluminum of the aluminum paste 60 for the rear electrode is diffused to the silicon substrate to form a p+ layer 40, and the aluminum paste 60 is transformed into an aluminum rear electrode 61, and the aluminum/silver paste 70 is transformed into an aluminum/silver rear electrode busbar 71. Simultaneously, the silver paste 50 for the front electrode finger line fires through the silicon nitride film during the firing to be electrically connected to the n-type layer 20 and transformed into a front electrode finger line 51 (see FIG. 2F).

(7) Formation of front electrode busbar: After the high temperature firing, shown in FIG. 2G, a front electrode busbar 80 having a width of 1.5 to 2 mm is printed with the conductive composition according to the exemplary embodiment of this invention by a screen printing, dried and then, fired at a low temperature, thereby manufacturing the silicon solar cell according to the exemplary embodiment of this invention.

The conductive composition used in manufacturing the front electrode busbar of the silicon solar cell according to the exemplary embodiment of this invention comprises a conductive powder, a curable resin, a reducing agent, and a curing agent. The conductive powder comprises a metallic powder and a solder powder.

The metallic powder included in the conductive composition according to the exemplary embodiment of this invention may act as a path for electron migration, serves to provide mechanical support, and provides strength and toughness required for the front electrode busbar. The metallic powder may use a metallic material with a melting point of 500° C. or more and which is capable of forming an intermetallic compound with the solder powder. As the metallic material, copper, nickel, gold, silver, and a combination thereof may be used. Nickel or copper is preferable in view of photovoltaic efficiency and economical efficiency. Copper is more preferable.

The metallic powder may have a shape such as a flake shape, a spherical shape, a spherical shape having protrusions, or the like. As an example, a scanning electron microscopic (SEM) photograph for a flake-shaped copper powder is shown in FIG. 3. The powder shape may influence reactivity with the solder and viscosity of the composition and thus a metallic powder with an appropriate shape is selected.

The metallic powder may be comprised in an amount of 1 to 50 vol % based on a total volume of the conductive composition. Within the range as above, proper viscosity for a process may be ensured and excellent electric conductivity may be acquired.

The solder powder included in the conductive composition according to the exemplary embodiment of this invention forms an intermetallic compound with the metallic powder to provide an electric path and increases adhesion, thereby increasing mechanical strength and toughness. The solder powder also adheres to the solder of the copper ribbon to entirely connect the copper ribbon coated with the solder and the metallic powder, and to entirely connect the metallic powders, thereby reducing electric resistance and increasing the strength. Since a firing temperature of the conductive composition for the front electrode busbar is the melting point or more of the solder powder, viscosity required for the process is low. After the firing process, the solder of a low temperature is fully transformed into the intermetallic compound and then, the remaining solder does not exist or only the unreacted metal having a high melting point remains. Accordingly, a phase change of the conductive composition material for the front electrode busbar does not occur during the high-temperature process after the firing process, thereby ensuring reliability of elements.

The solder powder may be a material comprising at least one selected from a group consisting of Sn, In, Bi, PB, Zn, Ga, Te, Hg, To, Sb, and Se which may form the intermetallic compound with the metallic powder and the copper ribbon coated with the solder. Preferably, the solder powder may be a material comprising at least one selected from a group consisting of Sn, In, SnBi, SnAgCu, SnAg, Sn, In, AuSin, and InSn.

The solder powder may also have a shape such as a flake shape, a spherical shape, a spherical shape having protrusions, or the like. Its particle size is defined by the IPC standard, J-STD-005 “Requirements for Soldering Paste”. Since an average particle diameter of the solder powder may influence the reducing force and the content of the reducing agent, the average particle diameter needs to be appropriately selected considering a correlation between two materials.

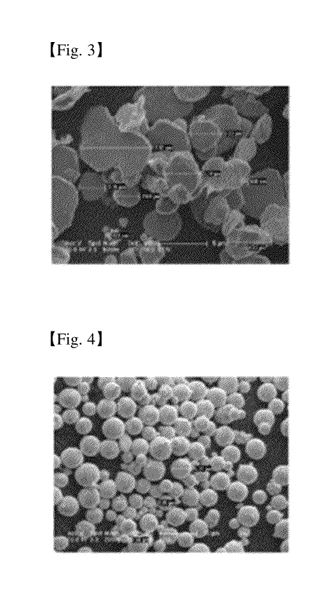

FIG. 4 is an SEM photograph illustrating a spherical solder powder according to an exemplary embodiment of this invention. The solder powder may be comprised in an amount of 1 to 50 vol % based on a total volume of the conductive composition for the front electrode busbar of the silicon solar cell. Within the range as above, proper viscosity for a process may be ensured and excellent electric conductivity may be acquired.

The reducing agent included in the conductive composition according to the exemplary embodiment of this invention serves to remove an oxide film of the metallic powder, the solder powder, and the copper ribbon coated with the solder to form the intermetallic compound by reacting with the solder powder, the metallic powder, and the solder of the copper ribbon.

Unlimited examples of the reducing agent may include acids including aldehydes, amines, or carboxyl groups. Acids including the carboxyl group are preferable. For example, the acids may be glutaric acid, malic acid, azelaic acid, abietic acid, adipic acid, ascorbic acid, acrylic acid, citric acid, or the like. The reducing agent may have a weight ratio of 0.5 to 20 phr to the curable resin. Within the range as above, it is possible to minimize bubble generation during the forming of the metallic compound.

The curable resin included in the composition according to the exemplary embodiment of this invention is an important factor for conveying the metallic powder, the solder powder, the reducing agent, the curing agent, and the like and determining the entire viscosity and has a characteristic in which the viscosity is reduced as the temperature increases. The curable resin is cured by reacting with the curing agent to serve to absorb the displacement according to a stress of metal or a thermal expansive coefficient. Particularly, the intermetallic compound has high brittleness to be easily broken due to the impact, but the intermetallic compound may have high toughness due to the cured resin, thereby mechanically and electrically increasing reliability. The curable resin also serves to prevent moisture from being permeated to the metal or intermetallic compound in an absorptive reliability test.

As the curable resin, an epoxy resin and a phenol resin which are generally known in the art may be used. Particularly, the epoxy resin is preferable. For example, the epoxy resin may be a bisphenol A-type epoxy resin (for example, DGEBA), a 4-functional epoxy resin (TGDDM), a 3-functional epoxy resin (TriDDM), isocyanate, bismaleimide, or the like, but is not limited thereto. Particularly, it is preferred that a material in which halogen is not included is used under the latest development trend of eco-friendly technologies. In case that the halogen is included, electrochemical migration easily occurs and as a result, a defect such as an electric short may occur. The curable resin may be comprised of an amount of 50 to 95 vol % based on a total volume of the conductive composition. Within the range as above, proper viscosity for a process may be ensured and excellent electric conductivity may be acquired.

The curing agent included in the conductive composition according to the exemplary embodiment of this invention serves to cure the resin by reacting with the curable resin. As unlimited examples of the curing agent, phenol-based curing agents, amide-based curing agents, amine-based curing agents, anhydride-based curing agents, and the like which are generally known are included. Amine-based agents such as meta phenylene diamine (MPDA), diamino diphenyl methane (DDM), diamino diphenyl sulfone (DDS), and the like; and anhydride-based curing agents such as methyl nadic anhydride (MNA), dodecenyl succinicanhydride (DDSA), maleic anhydride (MA), succinic anhydride (SA), methyltetrahydrophthalic anhydride (MTHPA), hexahydrophthalic anhydride (HHPA), tetrahydrophthalic anhydride (THPA), pyromellitic anhydride (PMDA), and the like may be preferably used. An equivalent ratio of the curing agent to the curable resin may be 0.4 to 1.2. Within the range as above, it is possible to minimize bubble generation during the reaction with the resin.

The curable resin, the reducing agent, and the curing agent may be separately added to the metallic powder and the solder powder or also be added after previously being mixed in a form of the composition.

Besides, the conductive composition according to the exemplary embodiment of this invention may further include silica having a low thermal expansive coefficient, a ceramic powder, or the like

The conductive composition according to the exemplary embodiment of this invention comprises the metallic powder of 1 to 50 vol %, the solder powder of 1 to 50 vol %, and the curable resin of 50 to 95 vol % based on a total volume of the composition, comprises the reducing agent having a weight ratio of 0.5 to 20 phr to the curable resin, and comprises the curing agent having an equivalent ratio of 0.4 to 1.2 to the curable resin.

The conductive composition according to the exemplary embodiment of this invention may be used for the front electrode busbar of the silicon solar cell. The conductive composition is printed and applied on the surface of the silicon solar cell with the front electrode finger line, dried, and then, the silicon solar cell is heated at the melting point or more of the solder powder, to form the front electrode busbar of the silicon solar cell and further to form the substrate including the front electrode busbar of the silicon solar cell.

The conductive composition for the front electrode busbar of the silicon solar cell according to the exemplary embodiment of this invention may be printed by using a general and simple screen printing, metal mask printing, or inkjet printing process.

The conductive composition for the front electrode busbar according to the exemplary embodiment of this invention is printed on the surface of the silicon solar cell with the front electrode finger line by using the above method, dried, and then, the silicon solar cell is heated at the melting point or more of the solder powder. The process may be performed for a sufficient time required for transition into the intermetallic compound by reaction of the entire solder powder with the metallic compound and generally, may be performed for 30 sec to 300 min. By this process, the solder powder entirely reacts with the metallic powder to be phase-transited into the metallic compound and as a result, meltingness of the solder is not observed in the subsequent process.

The conductive composition may comprise an intermetallic compound formed by the metallic powder and the solder powder, a porous matrix formed by the intermetallic compound and the metallic powder, and a cured resin filled in pores of the matrix.

Hereinafter, this invention will be described below in detail with reference to the example. However, the following example just exemplifies this invention, and this invention is not limited to the following Example.

### EXAMPLE

The silicon solar cell according to the exemplary embodiment of this invention was manufactured by the following process.

(1) A single crystalline silicon substrate of 156×156 mm p-type (Boron) having a thickness of 180 um was prepared, and POCl₃ was thermally diffused on the surface of the silicon substrate to form an n-type emitter and form a p-n junction with a p-type silicon.

(2) An n-type layer of the front surface of the silicon substrate was protected with a photoresist and the n-type layer of the rear surface thereof was removed through etching. When the photoresist of the front surface of the silicon substrate was removed by using organic solvent, only the n-type layer was left at the front surface of the silicon substrate.

(3) Silicon nitride film (SiNx) was deposited on the n-type layer by using a plasma enhanced chemical vapor deposition (PECVD) to form an anti-reflection film.

(4) An aluminum paste (Ferro 33-612) for a rear electrode was coated at the entire rear surface of the silicon substrate, and dried. An aluminum/silver paste (Ferro 33-601) for a rear busbar having a width of 2 mm was printed on the aluminum rear electrode by a screen printing, and dried. This is to connect to the copper ribbon coated with the solder used for connection with another silicon solar cell.

(5) The front electrode finger line was printed with a silver paste (Ferro NS33-5D/EX) for a front electrode by a screen printing, and dried. However, the front electrode busbar was not printed with the silver paste for a front electrode.

(6) The substrate was fired at a high temperature of 700° C. or more so as to form the front electrode and the rear electrode.

(7) After firing, the front electrode busbar having a width of 2 mm was printed with the conductive composition according to the exemplary embodiment of this invention (including epoxy-based diglycidylether bisphenol A (DGEBA) as the curable resin, a copper powder as the metallic powder, maleic acid as the reducing agent, a 58Sn/42Bi solder as the solder powder, diamino diphenyl sulfone (DDS) as the curing agent) by the screen printing, dried and then, fired at a low temperature of 200° C.

### COMPARATIVE EXAMPLE

Except that, in process (5) among the manufacturing processes according to the Example, the busbar in addition to the front electrode finger line was also printed with a silver paste (Ferro NS33-5D/EX) for a front electrode by the screen printing, dried, and that process (7) was not included, the silicon solar cell was manufactured by the same method as Example.

<Experimental Result>

Characteristics of the silicon solar cell according to the exemplary embodiment of this invention manufactured by Example and the conventional silicon solar cell manufactured by Comparative Example were measured with a commercial solar simulator (McScience K3000). Photovoltaic efficiency was measured through an I-V curve for measuring a photo-current by changing resistance under an AM 1.5 1 Sun lighting. The measurement result thereof was shown in Table 1.

TABLE 1

| Group | Photovoltaic Efficiency (%) |
|---|---|
| Example | 12.7 |
| Comparative Example | 12.5 |

The experiment shows that although the silicon solar cell according to the exemplary embodiment of this invention included less high-priced silver, the photovoltaic efficiency was more improved as compared with the conventional silicon solar cell.

From the foregoing, it will be appreciated that various embodiments of this invention have been described herein for purposes of illustration, and that various modifications may be made without departing from the scope and spirit of this invention. Accordingly, the various embodiments disclosed herein are not intended to be limiting, with the true scope and spirit being indicated by the following claims.

What is claimed is:

1. A silicon solar cell, comprising:
a silicon substrate having a p-n junction structure;
an anti-reflection film layer formed at the front surface of the silicon substrate;
a first electrode array electrically and mechanically connecting to the front surface of the silicon substrate through the anti-reflection film layer;
a second electrode formed at the rear surface of the silicon substrate; and
one or more third electrode electrically and mechanically connecting to the first electrode array, which is not connected with the front surface of the silicon substrate, and contains a conductive composition comprising a conductive powder, a curable resin, a reducing agent, and a curing agent.

2. The silicon solar cell of claim 1, wherein the anti-reflection film layer comprises silicon nitride.

3. The silicon solar cell of claim 1, wherein the conductive powder comprises a metallic powder and a solder powder.

4. The silicon solar cell of claim 3, wherein the metallic powder is a material having the melting point of 500° C. or more and is capable of forming an intermetallic compound with the solder powder.

5. The silicon solar cell of claim 3, wherein the metallic powder is at least one material selected from a group consisting of copper, nickel, silver, and gold.

6. The silicon solar cell of claim 5, wherein the metallic powder is copper.

7. The silicon solar cell of claim 3, wherein the solder powder is at least one material selected from a group consisting of Sn, In, Bi, Pb, Zn, Ga, Te, Hg, To, Sb, and Se.

8. The silicon solar cell of claim 3, wherein the solder powder is at least one material selected from a group consisting of Sn, In, SnBi, SnAgCu, SnAg, Sn, In, AuSin, and InSn.

9. The silicon solar cell of claim 1, wherein the curable resin is an epoxy resin.

10. The silicon solar cell of claim 1, wherein the reducing agent is an acid containing a carboxyl group (COOH—).

11. The silicon solar cell of claim 1, wherein the curing agent is at least one selected from a group consisting of amine-based curing agents and anhydride-based curing agents.

12. The silicon solar cell of claim 3, wherein the metallic powder is comprised in an amount of 1 to 50 vol %, the solder powder is comprised in an amount of 1 to 50 vol %, and the curable resin is comprised in an amount of 50 to 95 vol %, based on a total volume of the composition, the reducing agent is comprised in a weight ratio of 0.5 to 20 phr to the curable resin, and the curing agent having an equivalent ratio of 0.4 to 1.2 to the curable resin.

13. The silicon solar cell of claim 1, wherein the conductive composition further includes at least one material selected from silica and a ceramic powder.
